(19) United States
(12) Patent Application Publication
(10) Pub. No.: US 2010/0003423 A1
(43) Pub. Date: Jan. 7, 2010

(54) PLASMA GENERATING APPARATUS AND FILM FORMING APPARATUS USING PLASMA GENERATING APPARATUS

(75) Inventor: Hitoshi Nakagawara, Tokyo (JP)

Correspondence Address: FITZPATRICK CELLA HARPER & SCINTO, 1290 Avenue of the Americas, NEW YORK, NY, 10104-3800, US

(73) Assignee: CANON ANELVA CORPORATION, Kawasaki-shi (JP)

(21) Appl. No.: 12/541,002

(22) Filed: Aug. 13, 2009

Related U.S. Application Data
(63) Continuation of application No. PCT/JP2007/059339, filed on Apr. 24, 2007.

(51) Int. Cl. C23C 16/50; C23C 16/00; H05H 1/10; H05H 1/24

(52) U.S. Cl. 427/571; 118/723 R; 219/121.47

(57) ABSTRACT

The cross section of a beam is flattened by causing a plasma beam (25) extracted by a convergence coil from a plasma gun to pass through the magnetic field that extends to the direction orthogonal to the direction in which the plasma beam travels and is formed by magnets (27) made of permanent magnets which are oppositely arranged in pairs in parallel with each other. A plasma apparatus is provided using a plasma beam with 0.7≦Wi/Wt with a half-value of beam intensity with respect to a width Wt of a flattened beam 28 as Wi. At least one magnet is included which is stronger in intensity of a repulsive magnetic field at the center of the beam.

### CROSS-REFERENCES TO RELATED APPLICATIONS

This application is a continuation application of International Application No. PCT/JP2007/059339, filed on Apr. 24, 2007, the entire contents of which are incorporated by reference herein.

### TECHNICAL FIELD

The present invention relates to a plasma generating apparatus, a film forming apparatus and a film forming method using the plasma generating apparatus, and, in particular, to a film forming apparatus and a film forming method which are suited for forming a film on a large area substrate such as producing a plasma display panel, for example.

### BACKGROUND ARTS

In recent years, there has been strongly demanded the mass production of a large sized substrate for display such as a liquid crystal display (sometimes, represented by LCD in the description) and a plasma display panel (sometimes, represented by PDP in the description).

In forming a thin film such as an ITO transparent conductive film and MgO film being a front-plate electrode protecting layer on a large area substrate for display such as an LCD and a PDP, an ion plating method has drawn attention as a film forming method substituted for an EB vapor deposition method and a sputtering method as a production quantity increases and a panel becomes high in definition. The ion plating method has various advantages such as high film formation rate, high density film quality and a large process margin. The ion plating method allows forming a film on a large area substrate by controlling a plasma beam in a magnetic field. Among other things, a hollow cathode ion plating method, in particular, is expected as a method for forming a film on a large area substrate for display.

Some hollow cathode ion plating methods use a UR plasma gun developed by Joshin Uramoto as a plasma source (refer to Japanese Patent No. 1755055). The UR plasma gun is formed of a hollow cathode and a plurality of electrodes, lets Ar gas enter the gun to produce a high density plasma, changes the shape and path of a plasma beam under four different magnetic fields and conducts the beam to a film forming chamber. In other words, the plasma beam generated by the plasma gun is caused to pass through a magnetic field that extends to the direction orthogonal to the direction in which the plasma beam travels and is formed by magnets made of permanent magnets which are oppositely arranged in pairs in parallel with each other. Thereby, the plasma beam is deformed into a flat plasma beam.

There has been developed a technique for irradiating a vaporized material on a pan for the vaporized material with the plasma beam over the wide range (refer to Japanese Patent Application Laid-Open No. H09-78230). According to the technique, an evaporating material on a pan for the evaporating material, such as MgO, for example, is irradiated with the plasma beam over the wide range to enable a vapor source to be widened and formed on a wide substrate.

An example of a method of forming film using such a conventional film forming apparatus 100 is described with reference to FIGS. 11 and 12. FIG. 11 is a schematic side view describing an example of a conventional film forming apparatus. FIG. 12 is a schematic plane view of FIG. 11. FIG. 11 illustrates a view from a direction Y in FIG. 12. FIG. 12 illustrates a view from a direction X in FIG. 11.

A vaporized-material pan 32 containing a vaporized material (MgO, for example) 31 is placed at the lower portion of a film forming chamber (vacuum chamber) 30, from which air can be evacuated, of the film forming apparatus 100. A substrate 33 (a large substrate for display, for example) subjected to film formation is arranged at the upper portion of the film forming chamber 30 in opposition to the vaporized-material pan 32. When an ITO transparent conductive film or an MgO film is continuously formed on the substrate 33, the substrate 33 is continuously conveyed by a substrate holder (not shown) as indicated by an arrow 43 with a predetermined distance spaced.

In the embodiment illustrated in FIGS. 11 and 12, a plasma gun 20 disposed outside the film forming chamber 30 includes a hollow cathode 21, an electrode magnet 22, and an electrode coil 23 which are coaxially arranged along a substantially horizontal axis as illustrated in FIG. 11. The plasma gun 20 can be disposed in the film forming chamber 30.

A convergence coil 26 for extracting a plasma beam 25 into the film forming chamber 30 is arranged on the downstream side of the electrode coil 23 (in the direction in which the plasma beam travels).

On the further downstream side of the convergence coil 26, there are arranged magnets made of permanent magnets that extend to the direction intersecting the direction in which the plasma beam 25 travels and are oppositely arranged in pairs. As described above, the plasma beam 25 traveling toward the film forming chamber 30 passes through the magnetic field formed by the magnets into a plasma beam 28. A single or plural pair of magnets is arranged. In the conventional example illustrated in FIGS. 11 and 12, there are arranged two pairs of magnets 29 and 29.

In the conventional example illustrated in FIGS. 11 and 12, although the magnets 29 are arranged inside the film forming chamber 30, the magnets can be arranged outside the film forming chamber 30.

When a film is formed on the substrate 33, the vaporized material 31 is placed on the vaporized-material pan 32. The substrate 33 to be subjected to film formation is held with the substrate holder (not shown). Air is evacuated from the film forming chamber 30, as indicated by an arrow 42, to a predetermined vacuum level. Reactant gas is supplied to the film forming chamber 30 as indicated by an arrow 41.

In this condition, plasma gas such as argon (Ar) is let in the plasma gun 20 as indicated by an arrow 40. The plasma beam 25 generated by the plasma gun 20 is converged by the magnetic field formed by the convergence coil 26 and extracted into the film forming chamber 30 while being spread in a specific range and into a substantially circular cylindrical shape with a specific diameter in cross section. The plasma beam 25 passes through the magnetic fields each being formed by two pairs of magnets 29 and 29. When the plasma beam 25 passes through the pairs of magnets 29 and 29, the beam 25 turns into a flat plasma beam 28 deformed in cross section into a substantially rectangular or elliptic shape.

The plasma beam 28 is deflected by the magnetic field produced by an anode magnet 34 under the vaporized-material pan 32 and extracted on the vaporized material 31 to heat the vaporized material 31. Resultantly, the heated portion of the vaporized material 31 is vaporized and reaches the substrate 33 which is held by the substrate holder (not shown) and is moving in the direction indicated by the arrow 43 to form a film on the surface of the substrate 33.

### SUMMARY OF THE INVENTION

As described above, the conventional film forming apparatus 100 illustrated in FIGS. 11 and 12 and thus configured uses the conventional plasma generating apparatus in which the plasma beam generated by the plasma gun is caused to pass through the magnetic field formed by the magnets to form the deformed flat plasma beam.

The conventional plasma generating apparatus and the convention method using the film forming apparatus 100 enable widening a film formation area but have a problem to be solved with uniformity in film thickness.

According to experiments made by the inventors, it was observed that an ion flux distribution indicating the dispersion of the plasma beam on the surface of the vaporized material had such a characteristic as shown in FIG. 10 in the conventional method described above. In FIG. 10, an ordinate represents ion intensity (any average) and an abscissa represents a distance (mm) in the direction in which the beam is spread with the center of the plasma beam 28 taken as an original point (0) (in the direction indicated by the arrow x in FIG. 12).

A profile of the film formed on the surface of the substrate is also the same in shape as the above distribution, forms a peak which is thick in the center and gradually decreases in thickness toward the outer edge sides (both sides), which shows that uniformity in the distribution of film-thickness is insufficient when the film is formed on a wide-area substrate. This may be attributed to that in the plasma beam generated by the plasma gun traveling toward the film forming chamber 30 while being spread in a specific range and in a cylindrical shape with a specific diameter, for example, the plasma concentrates in the center of the plasma beam rather than on the outer edge side of the plasma beam. This makes the center side of the plasma beam higher in a vaporization rate of the irradiated vaporized material than the outer edge portions being the both sides of the center portion. As a result, the distribution of film-thickness becomes thick at the center and thin on the outer edge sides (both sides), which makes it inconvenient to form a film which is uniform in the distribution of film-thickness on a wide-area substrate.

The present invention has been made in view of the above problems and an object of the invention is to provide a plasma generating apparatus capable of increasing the area of film formation and further uniforming the distribution of thickness of a formed film, a film forming method and a film forming apparatus using the same.

To achieve the above object, the present invention puts forward the following proposal of a plasma generating apparatus in which the plasma beam, extracted by the convergence coil from the plasma gun, traveling while being spread in a specific range and in a cylindrical shape with a specific diameter, for example, is caused to pass through the magnetic field that extends to the direction orthogonal to the direction in which the plasma beam travels and is formed by magnets made of permanent magnets which are oppositely arranged in pairs in parallel with each other to be deformed.

A plasma apparatus according to the present invention includes a plasma gun, a magnet for applying a magnetic field to a plasma beam from the plasma gun to deform the cross section of the plasma beam into a substantially rectangular or elliptical shape and means for resting thereon an object irradiated with the plasma beam whose cross section is deformed, wherein the distribution of intensity of the plasma beam whose cross section is deformed into the substantially rectangular or elliptical cross section on the surface of the object irradiated with the plasma beam is represented by 0.4≦Wi/Wt, where Wt is a width in the longitudinal direction of the beam cross section and Wi is a width in which ion intensity is halved with respect to the maximum ion intensity (Imax) in the longitudinal direction on the object irradiated with the plasma beam. The relationship between the widths Wt and Wi in ion intensity distribution of the plasma apparatus of the present invention is represented by 0.7≦Wi/Wt in the embodiment.

The ion intensity distribution of the plasma beam specified in the contents of the application in the present invention is indirectly determined and defined from the depth of an irradiation indentation on the surface of the MgO sample plate caused by vaporizing the MgO material when the MgO sample plate with a flat surface is arranged on the plasma beam irradiation face of the plasma apparatus and irradiated with the plasma beam. The depth of an irradiation indentation may be regarded to be substantially proportional to the ion intensity of the plasma beam. The ion intensity is presumed from a relationship between the ion intensity and the depth of an irradiation indentation. The ion intensity in the maximum depth position of the irradiation indentation is taken as Imax and the half-value width of Imax is taken as Wi. In the present invention, the beam width (entire beam) Wt in the longitudinal direction of the beam cross-section is defined as a substantial beam width in a position where the depth of the irradiation indentation is equal to 1% of Imax.

To achieve the above object, in the film forming apparatus proposed by the present invention, a vaporized material placed on a vaporized-material pan disposed in a film forming chamber from which air can be evacuated is irradiated with plasma generated by any plasma generating apparatus according to the aforementioned present invention to vaporize the vaporized material, forming a film on a substrate arranged in a position opposing the vaporized-material pan with a predetermined interval spaced from the vaporized-material pan in the film forming chamber.

In this case, the substrate on which a film is formed can be moved inside the film forming chamber in parallel with the vaporized-material pan. Thereby, the film is continuously formed on the substrate to be moved.

To achieve the above object, in the film forming method proposed by the present invention, a vaporized material placed on a vaporized-material pan disposed in a film forming chamber from which air can be evacuated is irradiated with plasma generated by any plasma generating apparatus according to the aforementioned present invention to vaporize the vaporized material, forming a film on a substrate arranged in a position opposing the vaporized-material pan with a predetermined interval spaced from the vaporized-material pan in the film forming chamber.

In this case, the substrate on which a film is formed is moved inside the film forming chamber in parallel with the vaporized-material pan to allow the film to be continuously formed on the substrate to be moved. In the plasma generating apparatus of the present invention used in the film forming apparatus and the film forming method of the present invention, the plasma gun may be arranged outside the film forming chamber and the magnet may be arranged inside the film forming chamber. Alternatively, both the plasma gun and the magnet may be arranged outside the film forming chamber.

According to the plasma generating apparatus of the present invention, an ion flux distribution on the surface of the vaporized material is changed from a sharp angular shape with one peak, as illustrated in FIG. 10, to a flat shape in the longitudinal direction of the section of the beam, thereby flattening the profile of the film formed on the substrate to allow forming a film with a uniform distribution in thickness over a wide area.

According to the film forming apparatus and the film forming method, the profile of the film formed on the substrate can be flattened to allow forming a film with a uniform distribution in thickness over a wide area.

### BRIEF DESCRIPTION OF THE DRAWINGS

FIG. 1 is a schematic side view illustrating an example of a plasma generating apparatus and a film forming apparatus using the same according to the present invention,

FIG. 2 is a schematic plane view in FIG. 1,

FIG. 3A is a plan view illustrating a part of a magnet in an example in which the magnet is divided into three portions in the direction orthogonal to the plasma beam in the plasma generating apparatus of the present invention in the embodiment illustrated in FIGS. 1 and 2,

FIG. 3B is a plan view illustrating another configuration of a part of the magnet in the plasma generating apparatus of the present invention,

FIG. 3C is a plan view illustrating another example of a part of the magnet in the embodiment illustrated in FIG. 3B,

FIGS. 4A, 4B, 4C, 4D, and 4E are diagrams illustrating magnets and examples of arranging the magnets in the plasma generating apparatus of the present invention,

FIGS. 5A, 5B, and 5C are diagrams illustrating magnets and examples of arranging the magnets in the plasma generating apparatus of the present invention,

FIG. 6 is a chart showing an ion flux distribution formed on the surface of the vaporized material by the plasma beam generated by the conventional plasma generating apparatus using the conventional magnet and the plasma beam generated by the plasma generating apparatus of the present invention using the magnet in the embodiment illustrated in FIG. 4B,

FIG. 7 is a chart showing an ion flux distribution formed on the surface of the vaporized material by the plasma beam generated by the conventional plasma generating apparatus using the conventional magnet and the plasma beam generated by the plasma generating apparatus of the present invention using the magnet in the embodiment illustrated in FIG. 5B,

FIG. 8 is a chart showing another example of an ion flux distribution formed on the surface of the vaporized material by the plasma beam generated by the conventional plasma generating apparatus using the conventional magnet and the plasma beam generated by the plasma generating apparatus of the present invention using the magnet in the embodiment illustrated in FIG. 5B,

FIG. 9 is a chart showing the distribution of thickness of the film in the case where a film was formed using the plasma generating apparatus and the film forming apparatus of the present invention and using the conventional plasma generating apparatus and the film forming apparatus,

FIG. 10 is a chart illustrating an ion flux distribution in the conventional film forming apparatus,

FIG. 11 is a schematic side view illustrating an example of a conventional plasma generating apparatus and a conventional film forming apparatus using the same, and

FIG. 12 is a schematic plane view of FIG. 11.

### DETAILED DESCRIPTION OF EMBODIMENTS

An embodiment of the present invention is described below with reference to the accompanying drawings.

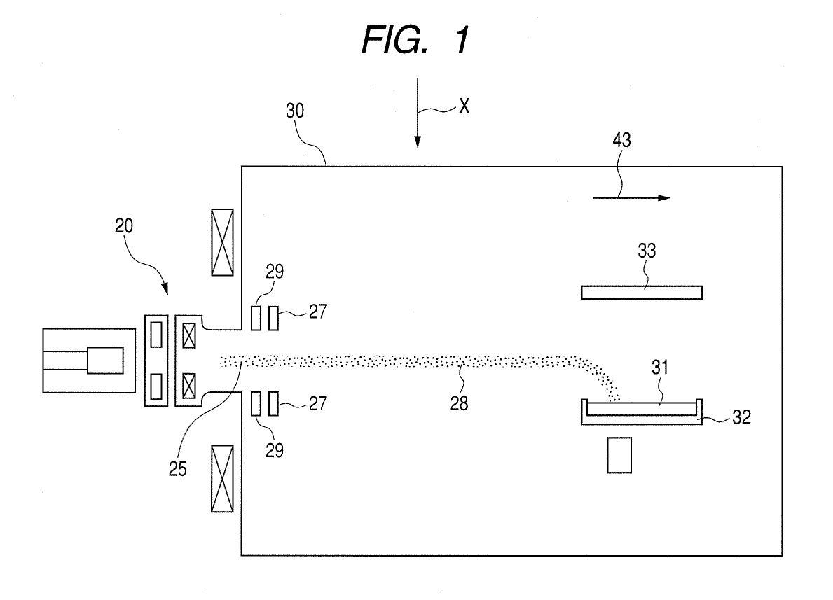

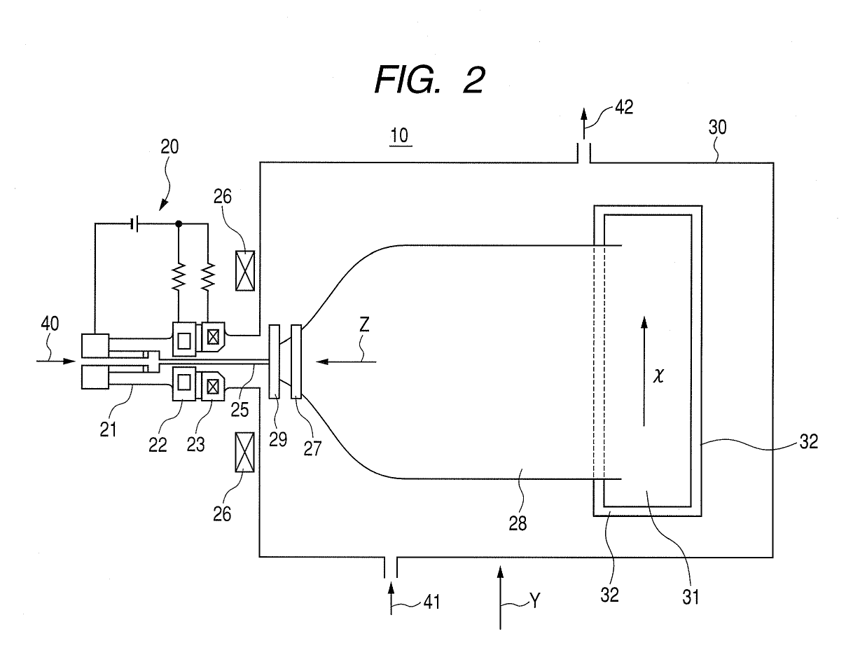

FIG. 1 is a schematic side view illustrating an example of a plasma generating apparatus and a film forming apparatus 10 using the same according to the present invention. FIG. 2 is a plane view illustrating a schematic configuration of the film forming apparatus 10 in FIG. 1. FIG. 1 illustrates a view from a direction Y in FIG. 2. FIG. 2 illustrates a view from a direction X in FIG. 1.

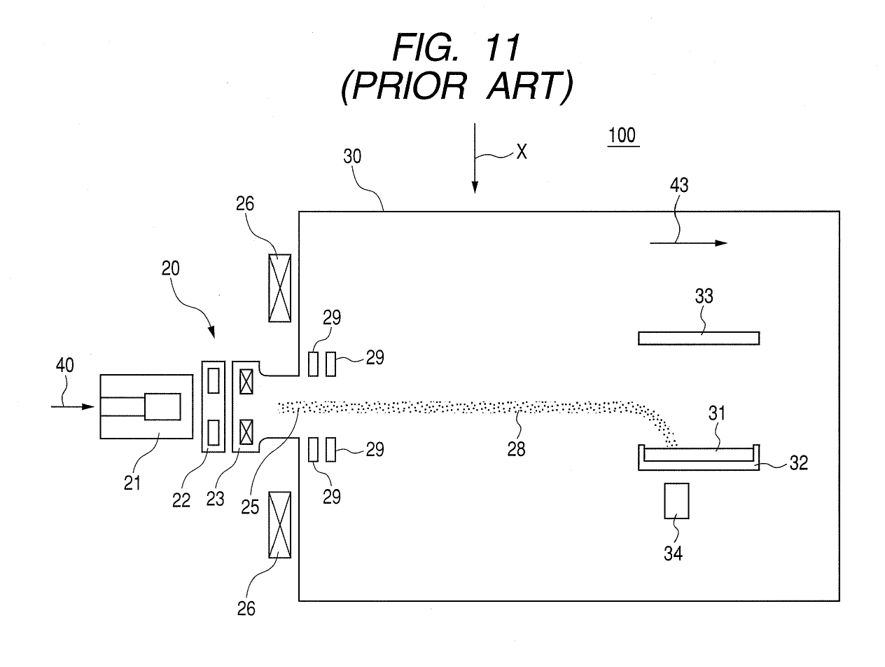

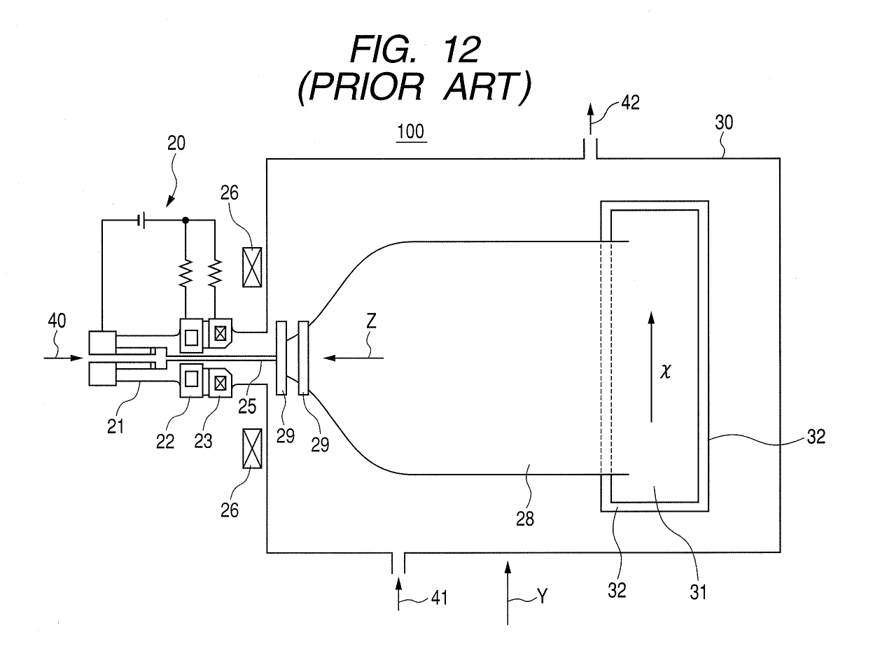

The present invention is characterized by the shape of a magnet 27 described later. The plasma generating apparatus and the film forming apparatus 10 excluding the magnet 27 are similar in configuration to the conventional plasma generating apparatus and the film forming apparatus 100 described in “BACKGROUND ART” in DESCRIPTION with reference to FIGS. 11 and 12, so that the portions common to those of the conventional plasma generating apparatus and the film forming apparatus 100 described in “BACKGROUND ART” in DESCRIPTION with reference to FIGS. 11 and 12 are denoted by the common reference numerals and characters to omit the description thereof.

The plasma beam 25 is extracted from the plasma gun 20 by the convergence coil 26. The plasma beam 25 passes through a magnetic field that extends to the direction orthogonal to the direction in which the plasma beam travels toward the film forming chamber 30 and is formed by the magnets 29 and 27 made of permanent magnets which are oppositely arranged in pairs in parallel with each other. Thereby, the plasma beam 25 turns into the plasma beam 28 illustrated in FIGS. 1 and 2.

As is the case with the conventional plasma generating apparatus described in “BACKGROUND ART” with reference to FIGS. 11 and 12, in the plasma generating apparatus of the present invention also, the plasma beam 25 traveling in a cylindrical shape with a specific diameter, for example, while being spread in a specific range is deformed in cross section by magnets into a substantially rectangular or elliptic shape flat plasma beam 28.

In the plasma generating apparatus of the present invention, the magnets includes at least one magnet 27 that is stronger in intensity of a repulsive magnetic field at a portion corresponding to the center of the plasma beam 25 than at a portion corresponding to the outer edge side of the plasma beam 25.

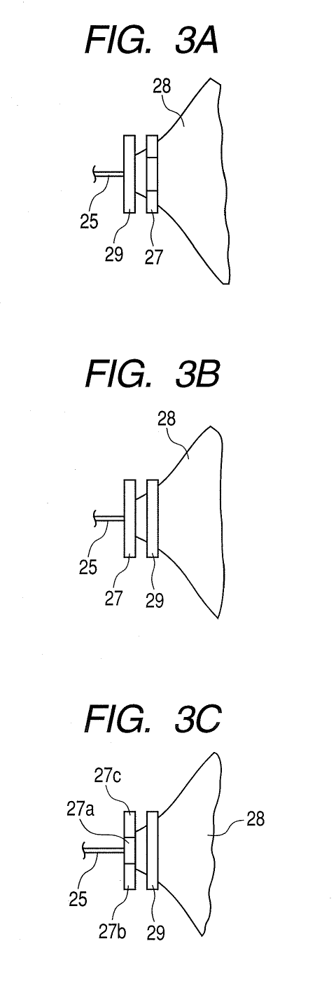

In the embodiment illustrated in FIGS. 1 to 3C, the magnet denoted by reference numeral 27 is stronger in intensity of a repulsive magnetic field at the portion corresponding to the center of the plasma beam 25 than at the portion corresponding to the outer edge side of the plasma beam 25. On the other hand, in FIGS. 1 to 3C, the magnet denoted by reference numeral 29 is a magnet which is used in a conventional plasma generating apparatus and has no difference in intensity of a repulsive magnetic field between the portion corresponding to the center of the plasma beam 25 and the portion corresponding to the outer edge side thereof. In the embodiment illustrated in FIGS. 1 to 3C, although two pairs of the magnets 27 and 29 are arranged in the direction in which the plasma beam 25 generated from the plasma gun 20 travels toward the film forming chamber 30, the present invention is not limited to such a configuration. If two or more pairs of the magnets are arranged, the magnets may include at least one magnet 27 that is stronger in intensity of a repulsive magnetic field at the portion corresponding to the center of the plasma beam 25 than at the portion corresponding to the outer edge side of the plasma beam 25. If a plurality of magnets are arranged and at least one of the plurality of magnets is the magnet 27 described above, the magnet 27 may be arranged close to the vaporized material 31 in the film forming chamber 30 as illustrated in FIGS. 1 and 2 or away from the vaporized material 31 in the film forming chamber 30 as illustrated in FIG. 3B.

Although not illustrated, only a pair of magnets 27 is arranged in the direction in which the plasma beam 25 traveling toward the film forming chamber 30, thereby the magnet 27 can be made stronger in intensity of a repulsive magnetic field at the portion corresponding to the center of the plasma beam 25 than at the portion corresponding to the outer edge side of the plasma beam 25.

The plasma beam 25 is flatly deformed in cross section by the magnets 27 and 29 into a flat beam 28 with which the plasma-beam irradiation material (vaporized material) 31 is irradiated on the vaporized-material table (pan) 32 in the film forming chamber 30 to vaporize the material 31, depositing the vaporized material on the substrate 33.

As is the case with the conventional example illustrated in FIGS. 11 and 12, in the embodiment illustrated in FIGS. 1 and 2, although the magnets 29 and 27 are arranged inside the film forming chamber 30, the magnets 27 and 29 may be arranged outside the film forming chamber 30.

At any rate, the magnets include at least one magnet 27 that is stronger in intensity of a repulsive magnetic field at the portion corresponding to the center of the plasma beam 25 than at the portion corresponding to the outer edge side of the plasma beam 25, allowing dispersing the density of the plasma passing through the center portion of the magnet 27 to the outer edge side. This enables the plasma to be prevented from concentrating at the center side rather than at the outer edge side when the vaporized material 31 arranged in the film forming chamber 30 is irradiated with the plasma beam 28. Thereby, the profile of the film formed on the substrate 33 is flattened to enable forming the film that is uniform in distribution of thickness.

In the plasma generating apparatus of the present invention, the magnet 27 that is stronger in intensity of a repulsive magnetic field at the portion corresponding to the center of the plasma beam 25 than at the portion corresponding to the outer edge side of the plasma beam 25 may be divided into plural portions in the direction orthogonal to the plasma beam 25.

This easily makes stronger intensity of a repulsive magnetic field at the portion corresponding to the center of the plasma beam 25 than at the portion corresponding to the outer edge side of the plasma beam 25 as described below.

FIG. 3A illustrates an example in which the magnet 27 is divided into three portions in the direction orthogonal to the plasma beam 25 in the plasma generating apparatus of the present invention in the embodiment illustrated in FIGS. 1 and 2.

FIG. 3C illustrates an example in which the magnet 27 is divided into three portions in the direction orthogonal to the plasma beam 25 in the plasma generating apparatus of the present invention in the embodiment illustrated in FIG. 3B.

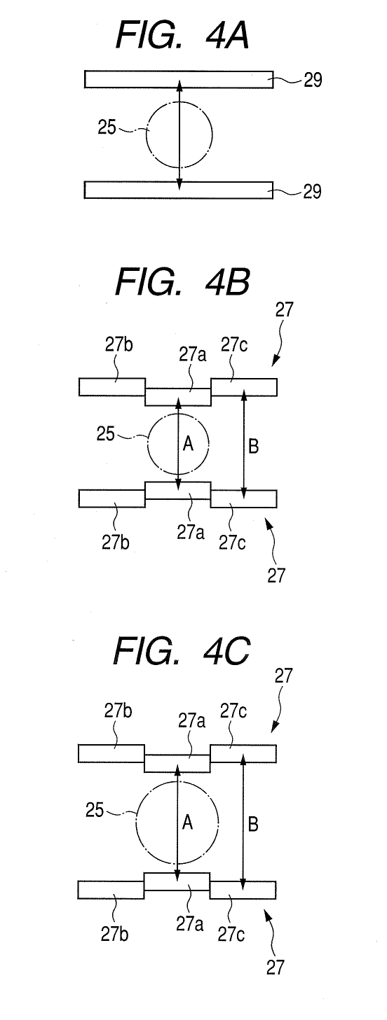

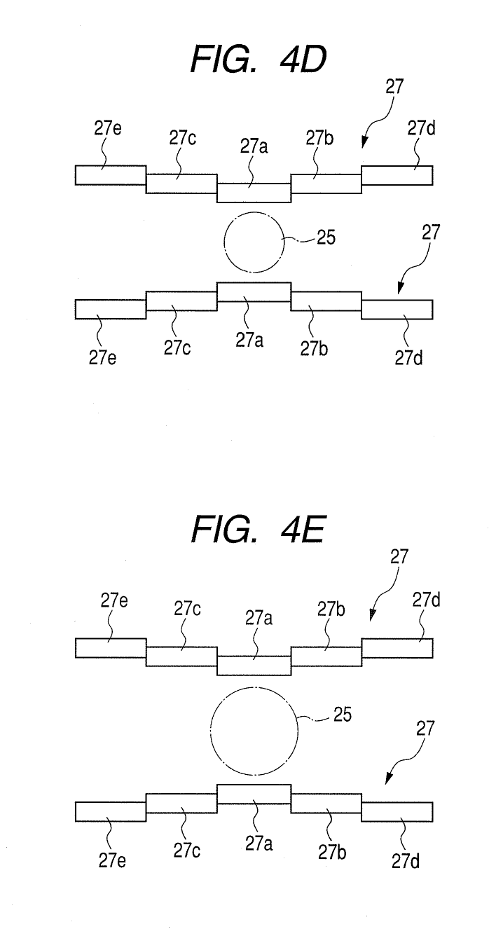

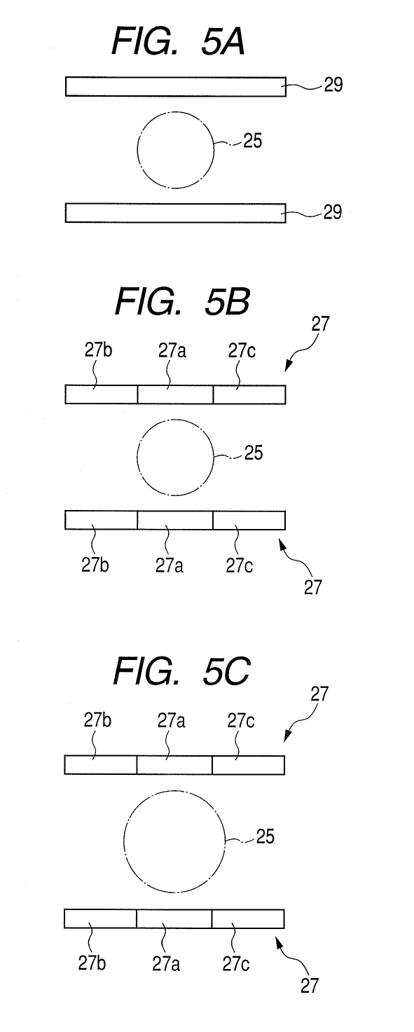

There are described below preferable examples of arrangement and configuration in which the magnet 27 is divided into plural portions in the direction orthogonal to the plasma beam 25 with reference to FIGS. 4A and 4B and FIGS. 5A to 5C.

FIGS. 4A to 4E and FIGS. 5A to 5C are diagrams illustrating arrangement and configuration of the magnet 29 used in the conventional plasma generating apparatus and the magnet 27 used in the plasma generating apparatus of the present invention when viewed from the direction Z indicated by the arrow in FIG. 2. FIG. 4A illustrates the arrangement of the magnet 29.

If the magnet 27 that is stronger in intensity of a repulsive magnetic field at the portion corresponding to the center of the plasma beam 25 than at the portion corresponding to the outer edge side of the plasma beam 25 is divided into plural portions in the direction orthogonal to the plasma beam 25, the magnet 27 may be arranged in the following configuration. In the magnet 27 divided into plural portions, for example, the permanent magnet in a part corresponding to the center of the plasma beam 25 is arranged closer to the plasma beam 25 than the permanent magnet in a part corresponding to the outer edge side of the plasma beam 25. A space between the permanent magnets opposing each other at the portion corresponding to the center is narrower than a space between the permanent magnets opposing each other at the portion corresponding to the outer edge side.

Dividing the magnet 27 into plural pieces in the direction orthogonal to the plasma beam 25 and arranging the magnet 27 in the above configuration easily make stronger intensity of a repulsive magnetic field at the portion corresponding to the center of the plasma beam 25 than at the portion corresponding to the outer edge side of the plasma beam 25, as described below.

FIGS. 4B and 4C illustrate examples in which the magnet 27 is divided into three portions in the direction orthogonal to the plasma beam 25 and the permanent magnets 27a and 27a in the part corresponding to the center of the plasma beam 25 are arranged closer to the plasma beam 25 than the permanent magnets 27b, 27b, 27c, and 27c in the part corresponding to the outer edge side of the plasma beam 25. This makes narrower a space A between the permanent magnets 27a and 27a opposing each other at the portion corresponding to the center than a space B between the permanent magnets 27b and 27b and a space B between the permanent magnets 27c and 27c opposing each other at the portion corresponding to the outer edge side.

FIG. 4A illustrates the magnet 29 which is used in the conventional plasma generating apparatus and has no difference in intensity of a repulsive magnetic field between the portions corresponding to the center and the outer edge side of the plasma beam 25. The permanent magnets opposing each other and being in pairs are the same in space both at the portion corresponding to the center of the plasma beam 25 and at the portion corresponding to the outer edge side of the plasma beam 25. Furthermore, the intensity of a repulsive magnetic field generated by the permanent magnets opposing each other is the same at any position.

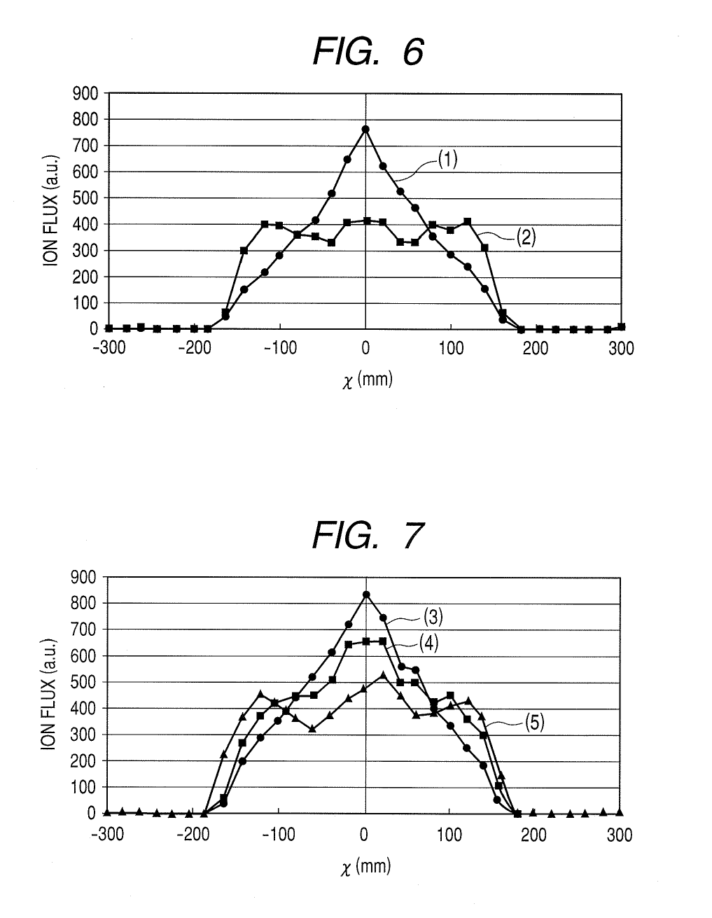

FIG. 6 shows an ion flux distribution (ion intensity distribution) formed on the surface of the vaporized material 31 by the plasma beam 28 generated with the same setting conditions in the conventional plasma generating apparatus using only the conventional magnet 29 in the configuration illustrated in FIG. 4A and in the plasma generating apparatus of the present invention in which the magnet 29 is replaced with the magnet 27 in the configuration illustrated in FIG. 4B.

According to the experiments made by the inventors, the conventional plasma generating apparatus using only the conventional magnet 29 in the configuration illustrated in FIG. 4A showed a sharp angular shape with one high peak in ion flux distribution as indicated by a line 1 in FIG. 6. On the other hand, the plasma generating apparatus of the present invention showed a gentle angular shape with a plurality of lower peaks in ion flux distribution as indicated by a line 2 in FIG. 6.

As a result, the distribution of plasma vaporizing the vaporized material 31 can also be similarly improved into a gentle angular shape. According to the film forming apparatus 10 of the present invention using the plasma generating apparatus of the present invention, it is enable to flatten the distribution of thickness of the film formed on the surface of the substrate 33, allowing forming a film with a uniform distribution in thickness over a wide area.

If the magnet 27 that is stronger in intensity of a repulsive magnetic field at the portion corresponding to the center of the plasma beam 25 than at the portion corresponding to the outer edge side of the plasma beam 25 is divided into plural portions in the direction orthogonal to the plasma beam 25, as exemplified in FIGS. 3A and 3C and FIGS. 4B and 4C, the number of divisions into a plural pieces is not limited to three in the direction orthogonal to the plasma beam 25. The intensity of a repulsive magnetic field is made stronger at the portion corresponding to the center of the plasma beam 25 than at the portion corresponding to the outer edge side of the plasma beam 25 to enable the magnet 27 to be divided into plural portions in the direction orthogonal to the plasma beam 25.

FIGS. 4D and 4E illustrate examples in which the magnet 27 that is stronger in intensity of a repulsive magnetic field at the portion corresponding to the center of the plasma beam 25 than at the portion corresponding to the outer edge side of the plasma beam 25 is divided into five portions of 27a to 27e in the direction orthogonal to the plasma beam 25. As is the case with the embodiment of FIGS. 4B and 4C, spaces between the permanent magnets 27b and 27b and the permanent magnets 27c and 27c opposing each other at the portion corresponding to the outer edge side are wider than a space between the permanent magnets 27a and 27a opposing each other at the portion corresponding to the center. Furthermore, spaces between the permanent magnets 27d and 27d and the permanent magnets 27e and 27e opposing each other at the outer edge sides are far wider.

As described above, if the magnet 27 that is stronger in intensity of a repulsive magnetic field at the portion corresponding to the center of the plasma beam 25 than at the portion corresponding to the outer edge side of the plasma beam 25 is divided into plural portions in the direction orthogonal to the plasma beam 25, the following configuration may be used. For example, the sheeted magnet 27 divided into plural portions is stronger in residual magnetic flux density of the permanent magnet at the portion corresponding to the center of the plasma beam 25 than at the portion corresponding to the outer edge side of the plasma beam 25. The intensity of a repulsive magnetic field generated by the permanent magnets opposing each other at the portion corresponding to the center is made stronger than at the portion corresponding to the outer edge side.

FIGS. 5B and 5C are diagrams illustrating the magnet 27 configured in the manner described above.

In the magnet 27 used in the plasma generating apparatus of the present invention, as illustrated in FIGS. 5B and 5C, for example, the central permanent magnet 27a out of the magnets 27 (27a, 27b, and 27c) divided into three portions in the direction orthogonal to the plasma beam 25 may be formed of neodymium magnet (Nd.Fe.B) in a strong magnetic field, for example, or samarium cobalt magnet (Sm.Co). Thereby, the intensity of a repulsive magnetic field generated by the permanent magnets 27a and 27a opposing each other at the portion corresponding to the center can be made stronger than the intensity of a repulsive magnetic field generated by the permanent magnets 27b and 27b and the permanent magnets 27c and 27c opposing each other at the portion corresponding to the outer edge side.

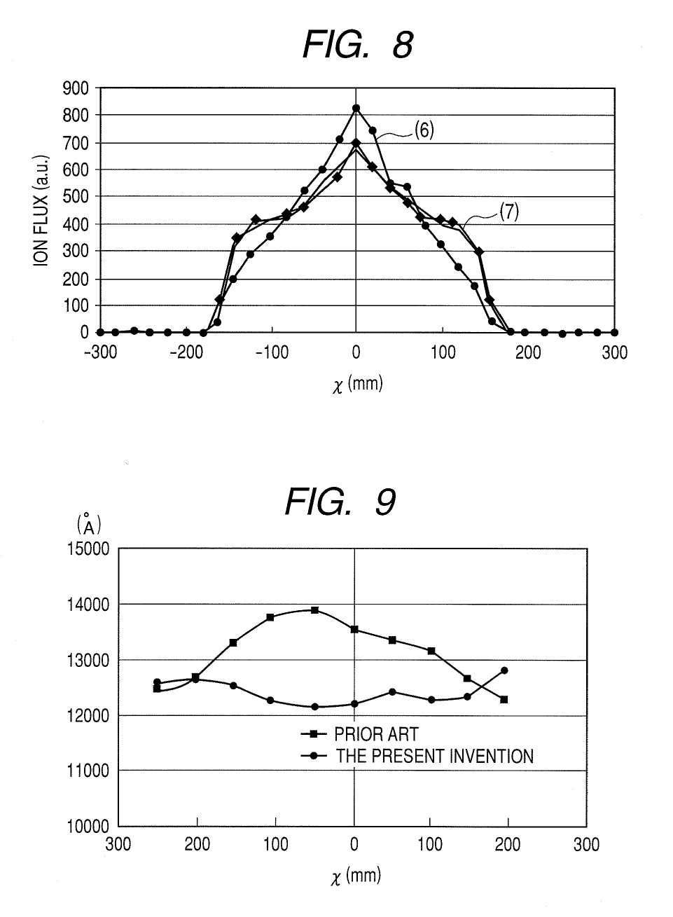

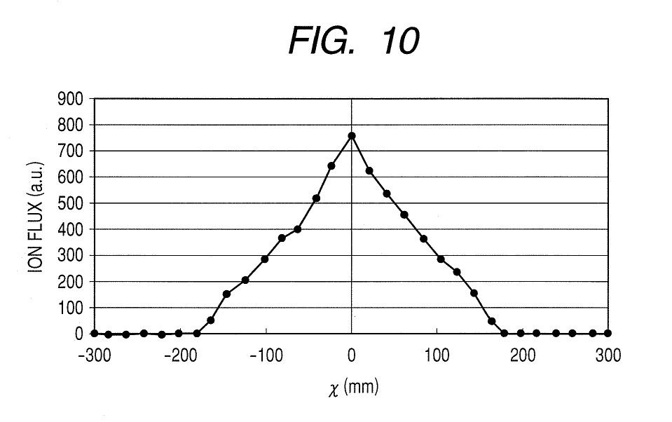

Although not illustrated, an area of the face of the central permanent magnet 27a opposing to the plasma beam 25 and its volume are made larger than those of the outer permanent magnets 27b and 27c, thereby the intensity of a repulsive magnetic field generated by the permanent magnets 27a and 27a opposing each other at the portion corresponding to the center can be made stronger than the intensity of a repulsive magnetic field generated by the permanent magnets 27b and 27b and the permanent magnets 27c and 27c opposing each other at the portion corresponding to the outer edge side. FIGS. 7 and 8 show ion flux distributions obtained when materials for the permanent magnets 27a, 27b, and 27c of the magnet 27 divided into three portions are changed.

In FIG. 7, a line 3 similar to the line 1 in FIG. 6 indicates the ion flux distribution in the conventional art. Lines 4 and 5 in FIG. 7 indicate ion flux distributions in the embodiment in which a neodymium magnet is used in the central permanent magnet 27a. In FIG. 7, the central permanent magnet 27a used for the line 5 is longer than that used for the line 4. For this reason, the outer permanent magnets 27b and 27c in the line 4 are shorter than those in the line 5. In FIG. 6, in the line 1, a half value is 382.5 because Imax=765 (a.u) and Wi at this point is 156 mm. In the line 2, Imax=425 (a.u), a half value is 212.5, and Wi at this point is 316 mm.

A ratio Wi/Wt to a total width (Wt=400 mm) of the plasma beam on the total irradiation surface is equal to 156/400=0.39 in the line 1 of FIG. 6 and 316/400=0.79 in the line 2 of FIG. 2. In other words, Wi/Wt is smaller than 0.4 in the conventional art. In the present invention, however, Wi/Wt is 0.4 or more. As indicated in FIG. 6, one high peak seen at the center of the plasma beam becomes small, which resultantly allows forming a film which is uniform in the distribution of thickness over a wide area of the substrate. In the line 4 of FIG. 7, Wi/Wt=0.71. In the line 5 of FIG. 7, Wi/Wt=0.85. Therefore, Wi/Wt is 0.7 or more in both lines in the embodiment of the present invention.

The ion intensity distribution of the plasma beam in FIGS. 6, 7, and 8 is indirectly determined and defined from the depth of an irradiation indentation on the surface of the MgO sample plate caused by vaporizing the MgO material when the MgO sample plate with a flat surface is arranged on the plasma irradiation face of the plasma apparatus and irradiated with the plasma beam. The depth of an irradiation indentation may be regarded to be substantially proportional to the ion intensity of the plasma beam. The ion intensity may be presumed from a relationship between the ion intensity and the depth of an irradiation indentation. The ion intensity in the maximum depth position of the irradiation indentation is taken as Imax and the half-value width of Imax is taken as Wi. In the present invention, the beam width (entire beam) Wt in the longitudinal direction of the beam cross-section is defined as a substantial beam width in a position where the depth of the irradiation indentation is equal to 1% of Imax.

In FIG. 8, a line 6 similar to the line 1 in FIG. 6 indicates the ion flux distribution in the conventional art. A line 7 in FIG. 8 indicates an ion flux distribution in the embodiment in which a samarium cobalt magnet is used in the central permanent magnet 27a.

In both cases where the materials high in residual magnetic flux density are used in the central permanent magnet 27a, the ion flux distribution becomes gentler in slope than the ion flux distribution indicating a sharp angular shape with one high peak as indicated by the line 1 in FIG. 6 in the conventional sheeted plasma generating apparatus using the conventional magnet 29 illustrated in FIGS. 4A and 5A.

As a result, the distribution of the plasma vaporizing the vaporized material 31 can be similarly made gentle in shape. The film forming apparatus 10 of the present invention using the plasma generating apparatus of the present invention can flatten the distribution of thickness of the film formed on the surface of the substrate 33 to allow forming a film which is uniform in the distribution of thickness over a wide area.

An example is described below in the case where a film is formed using the film forming apparatus 10 of the present invention illustrated in FIGS. 1 and 2 which uses the plasma generating apparatus of the present invention including the magnet 27 in FIG. 4C together with the conventional magnet 29 in FIG. 4A, as illustrated in FIG. 3A.

Argon gas as plasma gas is let in the plasma gun 20 as indicated by the arrow 40 and oxygen is let in the film forming chamber 30 as indicated by the arrow 41. Other than that, a configuration is given in the same manner as the conventional plasma generating apparatus and the film forming apparatus 100 described in “BACKGROUND ART” with reference to FIGS. 11 and 12. A film was formed on the substrate 33 in the following conditions:
Material: Magnesium oxide (MgO)
Thickness of film (target): 12000 Å
Discharge pressure: 0.1 Pa
Substrate temperature: 200° C.
Ar flow rate: 30 sccm (0.5 ml/sec)
O₂ flow rate: 400 sccm (6.7 ml/sec)
Film-forming speed: 175 Å/sec

A film was formed on another substrate 33 with two sets of magnets, both as the conventional magnets 29 illustrated in FIG. 4A, and other conditions remained unchanged.

FIG. 9 is a chart of measurements of distribution of thickness of the film in the case where a film was formed using the plasma generating apparatus and the film forming apparatus 10 of the present invention and using two sets of magnets, both as the conventional magnets 29 illustrated in FIG. 4A, as described above. In FIG. 9, an ordinate represents film thickness (A) and an abscissa represents a distance (mm) in the direction in which the plasma beam extends (in the direction indicated by an arrow x in FIG. 2) with the center of the plasma beam 28 as an original point (0).

As illustrated in FIG. 9, the distribution of thickness of the film was made flatter in the case where the film was formed using the plasma generating apparatus and the film forming apparatus 10 of the present invention rather than in the case described above.

Although the preferable embodiments of the present invention are described above with reference to the accompanied drawings, the present invention is not limited to the above embodiments, but various changes may be made within the scope delineated by the following claims.

1. A plasma apparatus including a plasma gun, a magnet for applying a magnetic field to a plasma beam from the plasma gun to deform the circular cross section of the plasma beam into a flat shape and means for resting thereon an object irradiated with the plasma beam having a deformed cross section, the plasma apparatus characterized in that
the distribution of intensity of the plasma beam having a deformed cross section into the flat cross section on the surface of the object irradiated with the plasma beam is represented by
0.4≦Wi/Wt≦1,
where Wt is a width in the longitudinal direction of the beam cross section and Wi is a width in which ion intensity is halved in the longitudinal direction of the beam cross section with respect to the maximum ion intensity (Imax) on the object irradiated with the plasma beam, and
the magnet includes a first magnet pair and a second magnet pair, each magnet pair comprising a pair of magnets, which are opposed to each other with being interposed by the plasma beam to apply a repulsive magnetic field to the plasma beam,
the first and second magnet pairs are juxtaposed in the plasma beam traveling direction and
in the intensity of repulsive magnetic field generated by at least one of the first and second magnet pairs, the intensity at the portion corresponding to the center of the plasma beam is stronger than that at the portion corresponding to the outer edge side of the plasma beam.

2. The plasma apparatus according to claim 1, wherein the relationship between the Wi and the Wt is represented by 0.7≦Wi/Wt.

3. (canceled)

4. A film forming apparatus characterized in that a vaporized material placed on a vaporized-material pan being means for resting thereon an object irradiated with plasma, the vaporized-material pan being disposed in a film forming chamber from which air can be evacuated, is irradiated with plasma generated by the plasma generating apparatus according to claim 1 to vaporize the vaporized material, forming a film on a substrate arranged in a position opposing the vaporized-material pan with a predetermined interval spaced from the vaporized-material pan in the film forming chamber.

5. The film forming apparatus according to claim 4, wherein the substrate on which a film is formed is moved inside the film forming chamber in parallel with the vaporized-material pan.

6. A film forming method charachterized in that a vaporized material placed on a vaporized-material pan disposed in a film forming chamber from which air can be evacuated is irradiated with plasma generated by the plasma generating apparatus according to claim 1 to vaporize the vaporized material, forming a film on a substrate arranged in a position opposing the vaporized-material pan with a predetermined interval spaced from the vaporized-material pan in the film forming chamber.

7. The film forming method according to claim 6, wherein the substrate on which a film is formed is moved inside the film forming chamber in parallel with the vaporized-material pan and the film is continuously formed on the substrate to be moved.
